(19) United States
(12) Patent Application Publication
(10) Pub. No.: US 2022/0263231 A1
(43) Pub. Date: Aug. 18, 2022

(54) DIGITAL PHASE SHIFTERS HAVING MULTI-THROW RADIO FREQUENCY SWITCHES AND RELATED METHODS OF OPERATION

(71) Applicant: CommScope Technologies LLC, Hickory, NC (US)

(72) Inventor: Michael Brobston, Allen, TX (US)

(21) Appl. No.: 17/626,184

(22) PCT Filed: Aug. 14, 2020
(86) PCT No.: PCT/US2020/046378

§ 371 Date: Jan. 11, 2022

Related U.S. Application Data
(60) Provisional application No. 62/907,048, filed on Sep. 27, 2019.

(51) Int. Cl. H01Q 1/24; H01Q 3/38; H01P 1/18; H03H 11/20; H03H 7/20; H03H 9/30

(52) U.S. Cl. CPC H01Q 1/246; H01Q 3/38; H03H 9/30; H03H 11/20; H03H 7/20; H01P 1/18

(57) ABSTRACT

Digital phase shifters are provided herein. A digital phase shifter includes first and second multi-throw RF switches that are coupled to each other by a plurality of delay lines having different respective lengths. In some embodiments, at least four delay lines couple the first and second multi-throw RF switches to each other. Related methods of operation are also provided.

### CROSS-REFERENCE TO RELATED APPLICATION

The present application claims priority to U.S. Provisional Patent Application No. 62/907,048, filed Sep. 27, 2019, the entire content of which is incorporated herein by reference.

### FIELD

The present disclosure relates to communication systems and, in particular, to phase shifters for radio frequency (“RF”) communications.

### BACKGROUND

Base station antennas for wireless communication systems are used to transmit RF signals to, and receive RF signals from, fixed and mobile users of a cellular communications service. Base station antennas often include a linear array or a two-dimensional array of radiating elements, such as crossed dipole or patch radiating elements. To change the down-tilt angle of the antenna beam generated by an array of radiating elements, a phase taper may be applied across the radiating elements. Such a phase taper may be applied by adjusting the settings on an adjustable phase shifter that is positioned along an RF transmission path between a radio and the individual radiating elements of the base station antenna.

One known type of phase shifter is an electromechanical rotating “wiper” arc phase shifter that includes a main printed circuit board (“PCB”) and a “wiper” PCB that may be rotated above the main PCB. Such a rotating wiper arc phase shifter typically divides an input RF signal that is received at the main PCB into a plurality of sub-components, and then capacitively couples at least some of these sub-components to the wiper PCB. These sub-components of the RF signal may be capacitively coupled from the wiper PCB back to the main PCB along a plurality of arc-shaped traces, where each arc has a different radius. Each end of each arc-shaped trace may be connected to a radiating element or to a sub-group of radiating elements. By physically rotating the wiper PCB above the main PCB, the location where the sub-components of the RF signal capacitively couple back to the main PCB may be changed, thereby changing the path lengths that the sub-components of the RF signal traverse when passing from a radio to the radiating elements. These changes in the path lengths result in changes in the phases of the respective sub-components of the RF signal, and because the arcs have different radii, the change in phase experienced along each path differs.

Typically, the phase taper is applied by applying positive phase shifts of various magnitudes (e.g., +X°, +2X° and)+3X° to some of the sub-components of the RF signal and by applying negative phase shifts of the same magnitudes (e.g., −X°, −2X° and −3X°) to additional of the sub-components of the RF signal. Thus, the above-described rotary wiper arc phase shifter may be used to apply a phase taper to the sub-components of an RF signal that are transmitted through the respective radiating elements (or sub-groups of radiating elements). Example phase shifters of this variety are discussed in U.S. Pat. No. 7,907,096, the disclosure of which is hereby incorporated herein by reference in its entirety. The wiper PCB is typically moved using an actuator that includes a direct current (“DC”) motor that is connected to the wiper PCB via a mechanical linkage. These actuators are often referred to as “RET” actuators because they are used to apply the remote electronic down-tilt. RET actuators can also apply down-tilt to non-rotational phase shifters, such as trombone or sliding dielectric phase shifters.

Another type of phase shifter is a digital phase shifter that uses RF switches to provide a phase shift. Conventional digital phase shifters, however, may experience passive intermodulation (“PIM”) distortion when they operate.

### SUMMARY

A digital phase shifter, according to some embodiments herein, may include a first phase shifter stage including first and second multi-throw RF switches that are coupled to each other by a first plurality of delay lines having different respective lengths. The digital phase shifter may include a second phase shifter stage including third and fourth multi-throw RF switches that are coupled to each other by a second plurality of delay lines having different respective lengths. The second multi-throw RF switch of the first phase shifter stage may be coupled to the third multi-throw RF switch of the second phase shifter stage.

In some embodiments, the digital phase shifter may include a third phase shifter stage including fifth and sixth multi-throw RF switches that are coupled to each other by a third plurality of delay lines having different respective lengths. The fourth multi-throw RF switch of the second phase shifter stage may be coupled to the fifth multi-throw RF switch of the third phase shifter stage.

According to some embodiments, the first and second phase shifter stages may be in a first sub-array of a phase shift array. The phase shift array may also include: a second sub-array including a second plurality of phase shifter stages; a third sub-array including a third plurality of phase shifter stages; and a fourth sub-array including a delay line that is not coupled to any multi-throw RF switch.

In some embodiments, the digital phase shifter may include a power divider that is coupled to the first through fourth sub-arrays. Moreover, the digital phase shifter may include a high-voltage driver that is coupled to the first through third sub-arrays.

According to some embodiments, the digital phase shifter may be coupled to radiating elements of a base station antenna. Moreover, the digital phase shifter may include a decoder that is coupled to the first through third sub-arrays and is configured to translate information relating to an amount of tilt of the base station antenna into a state of the digital phase shifter. Alternatively, the digital phase shifter may include first through third decoders that are coupled to the first through third sub-arrays, respectively.

In some embodiments, the digital phase shifter may include a storage device that is coupled to, and configured to hold a state of, the digital phase shifter. The storage device may include a capacitor or a non-volatile memory.

According to some embodiments, the first through fourth multi-throw RF switches may be respective RF microelectromechanical systems (“MEMS”) switches. Moreover, the digital phase shifter may be a time division duplex (“TDD”) digital phase shifter.

A digital phase shifter, according to some embodiments herein, may include first and second multi-throw RF switches that are coupled to each other by at least four delay lines having different respective lengths. In some embodiments, the digital phase shifter may include third and fourth multi-throw RF switches that are coupled to each other by at least four delay lines having different respective lengths. Moreover, the second and third multi-throw RF switches may be coupled to each other.

A method of operating a base station antenna including a digital phase shifter, according to some embodiments herein, may include selecting, via first and second multi-throw RF switches that are coupled to each other by at least four delay lines having different respective lengths, a state of the digital phase shifter. Moreover, the method may include translating information relating to an amount of tilt of the base station antenna into the state of the digital phase shifter.

In some embodiments, the first and second multi-throw RF switches may be first and second RF MEMS switches, respectively. Moreover, the selecting may include actuating the first and second RF MEMS switches via at least one high-voltage driver. The actuating may include applying the amount of tilt to a vertical column of radiating elements coupled to the digital phase shifter, without using any RET motor.

According to some embodiments, the translating may be performed by at least one decoder coupled to the digital phase shifter. Moreover, the digital phase shifter may operate in a TDD mode of the base station antenna and/or the method may include using a capacitor or a non-volatile memory to hold the state of the digital phase shifter.

### BRIEF DESCRIPTION OF THE DRAWINGS

FIG. 1 is a front perspective view of a base station antenna according to embodiments of the present inventive concepts.

FIG. 2A is a schematic front view of the base station antenna of FIG. 1 with the radome removed.

FIG. 2B is a schematic block diagram of the vertical columns of FIG. 2A coupled to phase shifters.

FIGS. 3A-3C are schematic plan views of digital phase shifters according to embodiments of the present inventive concepts.

FIGS. 4A and 4B are flowcharts illustrating operations of a base station antenna that includes a digital phase shifter, according to embodiments of the present inventive concepts.

### DETAILED DESCRIPTION

Pursuant to embodiments of the present inventive concepts, digital phase shifters for wireless communications are provided. In wireless communications, it may be desirable to use base station antennas having multiple columns of radiating elements. It may also be desirable to electronically adjust the elevation angle of an antenna beam to adjust the coverage area of the antenna. This can be done for each column separately, such as by using phase shifters.

According to embodiments of the present inventive concepts, digital phase shifters are provided that may apply down-tilt without using RET actuators (i.e., without using any RET motor). Digital phase shifters can thus reduce the size, weight, and cost of base station antennas, as RET actuators and associated mechanical linkages may be omitted from base station antennas that use digital phase shifters. Moreover, though digital phase shifters can be susceptible to PIM distortion, digital phase shifters according to embodiments of the present inventive concepts may include high-power RF MEMS switches that experience sufficiently-low PIM distortion to facilitate TDD operation by the digital phase shifters. The high-power RF MEMS-based digital phase shifters may have lower insertion loss than conventional electromechanical phase shifters.

In some embodiments, a quaternary MEMS phase shifter can be constructed using single-pole four-throw RF MEMS switches with delays that are implemented using various lengths of meandering transmission lines. This can provide, for example, a sixteen-state phase shifter or variable delay line that is fully implemented on a PCB and that provides control using a four-bit digital control interface. The four-bit digital control interface may be converted through decoding logic (a decoder) to create state control for each switch. This control can be common across each tap of a delay (or other conductive) line, or each tap may have unique control.

Moreover, it may be desirable for a phase shifter to retain a phase state that is set, even if DC power is removed. Accordingly, in some embodiments, such as when using a MEMS switch that can maintain a fixed switch state with a low current, an actuation voltage for the MEMS switch can be stored in a large capacitor that can hold the actuation voltage relatively stable despite the removal of DC power. The actuation voltage may be a high voltage that actuates (e.g., electrostatically actuates) the MEMS switch. For example, a high voltage may cause a cantilever to close a contact of the MEMS switch to enable the MEMS switch to select between different states.

Example embodiments of the present inventive concepts will be described in greater detail with reference to the attached figures.

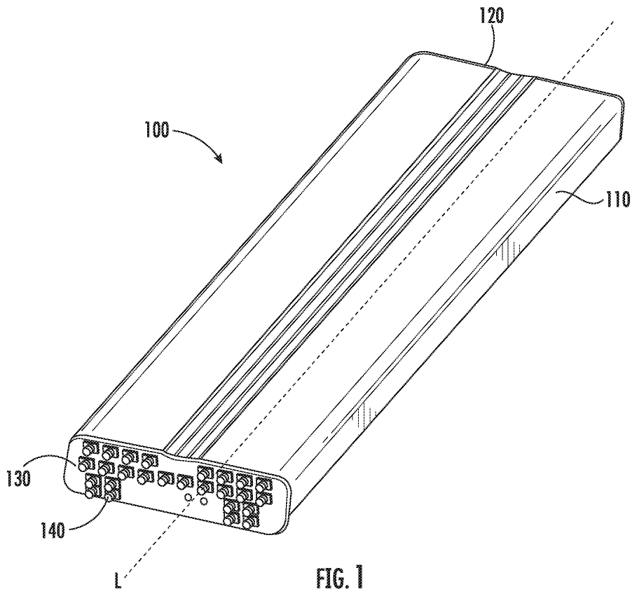

FIG. 1 is a front perspective view of a base station antenna 100 according to embodiments of the present inventive concepts. As shown in FIG. 1, the antenna 100 is an elongated structure and has a generally rectangular shape. The antenna 100 includes a radome 110. In some embodiments, the antenna 100 further includes a top end cap 120 and/or a bottom end cap 130. For example, the radome 110, in combination with the top end cap 120, may comprise a single unit, which may be helpful for waterproofing the antenna 100. The bottom end cap 130 is usually a separate piece and may include a plurality of connectors 140 mounted therein. The connectors 140 are not limited, however, to being located on the bottom end cap 130. Rather, one or more of the connectors 140 may be provided on the rear (i.e., back) side of the radome 110 that is opposite the front side of the radome 110. The antenna 100 is typically mounted in a vertical configuration (i.e., the long side of the antenna 100 extends along a vertical axis L with respect to Earth).

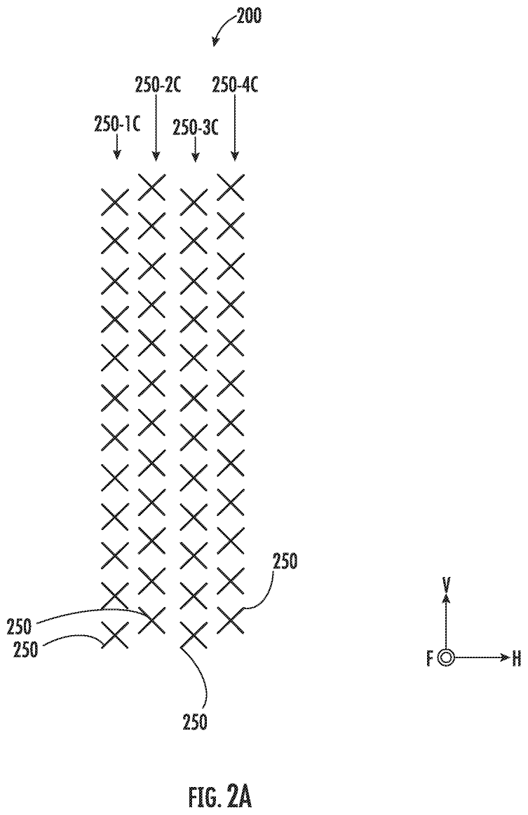

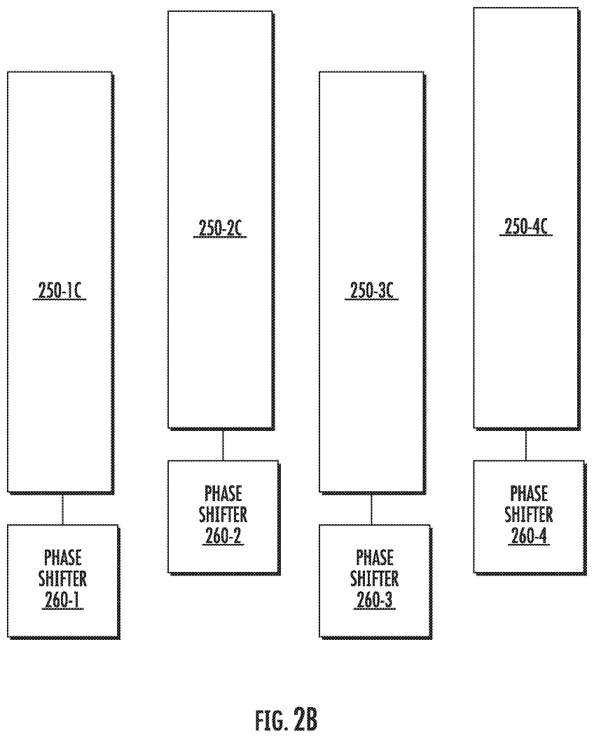

FIG. 2A is a schematic front view of the base station antenna 100 of FIG. 1 with the radome 110 thereof removed to illustrate an antenna assembly 200 of the antenna 100. The antenna assembly 200 includes a plurality of radiating elements 250, which may be grouped into one or more arrays, including one or more beam-forming arrays.

Vertical columns 250-1C through 250-4C of the radiating elements 250 may extend in a vertical direction V from a lower portion of the antenna assembly 200 to an upper portion of the antenna assembly 200. The vertical direction V may be, or may be in parallel with, the longitudinal axis L (FIG. 1). The vertical direction V may also be perpendicular to a horizontal direction H and a forward direction F. As used herein, the term “vertical” does not necessarily require that something is exactly vertical (e.g., the antenna 100 may have a small mechanical down-tilt). The radiating elements 250 may extend forward in the forward direction F from one or more feeding (or “feed”) boards that couple RF signals to and from the individual radiating elements 250. For example, the radiating elements 250 may, in some embodiments, be on the same feeding board. As an example, the feeding board may be a single PCB having all of the radiating elements 250 thereon. Cables may be used to connect each feeding board to other components of the antenna 100, such as diplexers, phase shifters, or the like. In some embodiments, the feeding boards may be omitted and the radiating elements 250 may be connected by cables to other components of the antenna 100.

Though FIG. 2A illustrates the four vertical columns 250-1C through 250-4C, the antenna assembly 200 may include more (e.g., five, six, seven, eight, or more) or fewer (e.g., two or three) vertical columns of the radiating elements 250. Moreover, the number of radiating elements 250 in a vertical column can be any quantity from two to twenty or more. For example, the vertical columns 250-1C through 250-4C may each have twelve to twenty radiating elements 250.

In some embodiments, the antenna assembly 200 may include a plurality of radiating elements (not shown) that are configured to operate in a frequency hand different from that of the radiating elements 250. For example, the vertical columns 250-1C through 250-4C may be “inner” vertical columns of high-band radiating elements that are between, in the horizontal direction H, vertical columns of low-band radiating elements. Moreover, the radiating elements 250, and/or other (e.g., low-band) radiating elements of the antenna assembly 200, may comprise dual-polarized radiating elements that are mounted to extend forwardly in the forward direction F from feeding board(s).

The radiating elements 250 may, in some embodiments, be high-band radiating elements that are configured to transmit and receive signals in a high frequency band comprising one of the 1400-2700 megahertz (“MHz”), 3300-4200 MHz, and/or 5000-5900 MHz frequency ranges or a portion thereof. By contrast, low-band radiating elements may be configured to transmit and receive signals in a low frequency band comprising the 617-960 MHz frequency range or a portion thereof.

In some embodiments, the radiating elements 250 may be used in a beam-forming mode to transmit RF signals where the antenna beam is “steered” in at least one direction. Examples of antennas that may be used as beam-forming antennas are discussed in U.S. Patent Publication No. 2018/0367199, the disclosure of which is hereby incorporated herein by reference in its entirety. For example, a base station may include a beam-forming radio that has a plurality of output ports that are electrically connected to respective ports of a base station antenna.

Various mechanical and electronic components of the antenna 100 (FIG. 1) may be mounted in a chamber behind a back side of the feeding board(s) and/or a reflector. The components may include, for example, phase shifters, a controller, diplexers, and the like.

FIG. 2B is a schematic block diagram of the vertical columns 250-1C through 250-4C of FIG. 2A coupled (e.g., electrically connected) to phase shifters 260-1 through 260-4, respectively. Each phase shifter 260 controls the phase shift between radiating elements 250 (FIG. 2A), or sub-arrays of radiating elements 250, of the vertical column that is coupled to that phase shifter 260. Moreover, each phase shifter 260 may be (a) a digital phase shifter rather than (b) a rotational (e.g., wiper) phase shifter or a non-rotational (e.g., trombone or sliding dielectric) phase shifter whose movement is controlled by a RET actuator.

In some embodiments, each phase shifter 260 may be a TDD digital phase shifter. For example, the phase shifters 260 may include high-power RF MEMS switches that experience sufficiently-low PIM distortion to facilitate TDD operation. Alternatively, the phase shifters 260 may include other RF switches, such as mechanical relays, gallium arsenide (“GaAs”) field-effect transistor (“FET”) devices, or PIN diode devices. Though FIG. 2B illustrates one phase shifter 260 per vertical column (or array/sub-array) of radiating elements 250, if dual-polarized radiating elements are used, two phase shifters 260 may be provided per vertical column (or array/sub-array).

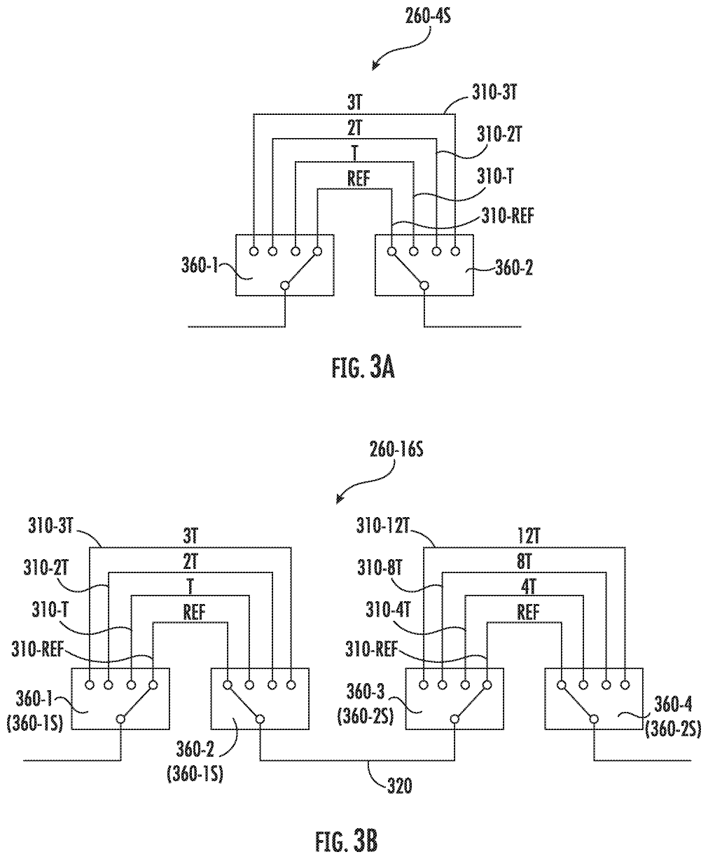

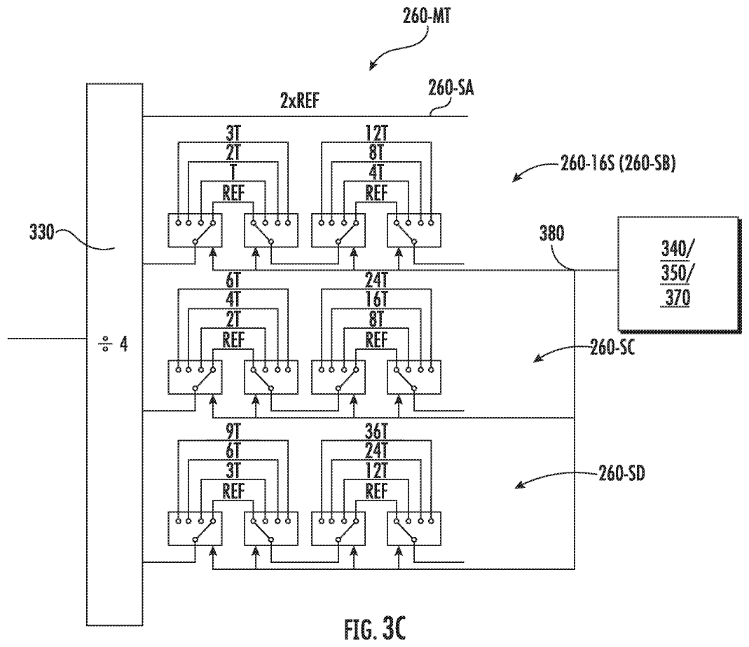

FIGS. 3A-3C are schematic plan views of digital phase shifters 260 according to embodiments of the present inventive concepts. As shown in FIG. 3A, a four-state digital phase shifter 260-4S may include a pair of multi-throw RF switches 360-1 and 360-2. The switches 360-1 and 360-2 may be coupled to each other by four delay lines 310-REF, 310-T, 310-2T, and 310-3T that have different respective lengths. To select a delay of REF, the switches 360-1 and 360-2 select their respective throws (e.g., terminals) that are coupled to the shortest delay line 310-REF. Likewise, to select a longer delay of REF+T, the switches 360-1 and 360-2 select their respective throws that are coupled to the longer delay line 310-T. Moreover, to select a still longer delay of REF+2T, the switches 360-1 and 360-2 select their respective throws that are coupled to the still longer delay line 310-2T, and to select a delay of REF+3T, the switches 360-1 and 360-2 select their respective throws that are coupled to the delay line 310-3T. The symbol “T,” as used herein with respect to a delay, refers to a non-zero amount of time/angle delay, such as 10 nanoseconds and/or about 1-2 degrees.

Each delay line 310 can be implemented using various techniques, including a PCB transmission line (or other type of meandering line), a coaxial cable, a surface acoustic wave (“SAW”) delay line, a bulk acoustic wave (“BAW”) delay line, or a cavity delay line. In some embodiments, microstrip delay lines on a PCB may be coupled to PCB-mounted switches 360. Alternatively, a suspended strip line may be used, which may reduce losses. Moreover, a delay line 310 may, in some embodiments, be shaped like a square wave or a sine wave.

The following Table 1 illustrates the amount of delay that is provided by each state of the phase shifter 260-4S. As used herein, the delay of REF may also be indicated as “Ref.” The phase shifter 260-4S offers four different delay settings to provide a controllable time delay or phase shift. For simplicity of explanation, REF is assumed to be a very small value that is approximated as zero. Accordingly, though the delays T, 2T, and 3T shown in Table 1 are technically REF+T, REF+2T, and REF+3T, respectively, they are shown without REF because it is approximated as zero. Moreover, the delays for the four states may alternatively be 0.5T (i.e., REF=0.5T), REF+1.5T, REF+2.5T, and REF+3.5T, respectively, or 0.5T, REF+4.5T, REF+8.5T, and REF+12.5T, respectively.

TABLE 1

| State | Delay |
|---|---|
| 00 | Ref |
| 01 | T |
| 02 | 2T |
| 03 | 3T |

Referring to FIG. 3B, a sixteen-state digital phase shifter 260-16S may include two phase shifter stages that are coupled to each other. For example, the first phase shifter stage may be the four-state digital phase shifter 260-4S (FIG. 3A). Accordingly, the switches 360-1 and 360-2 of the four-state digital phase shifter 260-4S may be a pair of first phase shifter stage switches 360-1S. The second phase shifter stage may be another four-state digital phase shifter, which includes a pair of multi-throw RF switches 360-3 and 360-4 that are coupled to each other by four delay lines 310-REF, 310-4T, 310-8T, and 310-12T that have different respective lengths. The switches 360-3 and 360-4 may thus be a pair of second phase shifter stage switches 360-2S. The switch 360-2 of the first phase shifter stage may be coupled to the switch 360-3 of the second phase shifter stage by a conductive line 320.

Though FIG. 3B shows two phase shifter stages that are coupled to each other, a digital phase shifter 260 may, in some embodiments, include three, four, or more stages that are coupled to each other. For example, a third phase shifter stage may include a pair of multi-throw RF switches 360 that are coupled to each other by four delay lines 310 that have different respective lengths. One of the switches 360 of the third phase shifter stage may be coupled to the switch 360-4 of the second phase shifter stage by a conductive line. For each stage that is added, another digit is added for state control. Moreover, in some embodiments, an octal or hexadecimal numerical system may be used.

The following Table 2 illustrates the amount of delay that is provided by each state of the phase shifter 260-16S. The phase shifter 260-16S provides a larger number of phase or time delay increments than the phase shifter 260-4S (FIG. 3A) by combining multiple stages of multi-throw phase shifters. In particular, the phase shifter 260-16S is a quaternary phase shifter that provides sixteen selectable states. The first stage, including the pair of first phase shifter stage switches 360-1S, provides the same delay states as the phase shifter 260-4S. The second stage, including the pair of second phase shifter stage switches 360-2S, provides delay states of REF, REF+4T, REF+8T, and REF+12T. By combining these two stages, it is possible to provide selectable states of 2REF+nT, where n=0 to 15.

TABLE 2

| State | Delay |
|---|---|
| 00 | Ref |
| 01 | T |
| 02 | 2T |
| 03 | 3T |
| 10 | 4T |
| 11 | 5T |
| 12 | 6T |
| 13 | 7T |
| 20 | 8T |
| 21 | 9T |
| 22 | 10T |
| 23 | 11T |
| 30 | 12T |
| 31 | 13T |
| 32 | 14T |
| 33 | 15T |

Though the examples herein are shown using four-state switches 360, the same approach can be implemented with any other number of switch throws. For example, using two eight-throw switches, an eight-state (or eight-step) phase shifter can be constructed. By cascading two of these eight-state phase shifters, a sixty-four-state phase shifter can be constructed. Switches with different numbers of states may also be combined (e.g., an eight-state switch may be coupled to a four-state switch).

Referring to FIG. 3C, a multi-tap digital phase shifter 260-MT may be a phase shift array that includes multiple sub-arrays that are coupled to a vertical column of radiating elements 250 (FIG. 2A). As an example, the sixteen-state digital phase shifter 260-16S may be a sub-array 260-SB of the array. The array may also include multi-stage sub-arrays 260-SC and 260-SD. For example, the sub-arrays 260-SC and 260-SD, like the sub-array 260-SB, may each include two four-state phase shifter stages. In some embodiments, however, the sub-arrays 260-SB through 260-SD may each include three, four, or more phase shifter stages, and/or the array may include four, five, six, or more multi-stage sub-arrays.

Moreover, the array may include a sub-array 260-SA comprising a delay line that is not coupled to any multi-throw RF switch 360 (FIG. 3B). Accordingly, the sub-array 260-SA is free of any multi-throw RF switch 360, and its delay line may extend the length of two stages of a multi-stage sub-array, thereby providing a delay of 2×REF. In some embodiments, the sub-array 260-SA, which has the shortest-length delay line and provides the least phase delay, may be at the lowest end of the array, and thus may be lower (e.g., in a direction parallel to the longitudinal axis L) in a base station antenna 100 (FIG. 1) than the sub-arrays 260-SB through 260-SD. The highest sub-array 260-SD may provide the most phase delay.

Each of the sub-arrays 260-SA through 260-SD may be coupled to a power divider 330, which may be an equal, four-way power divider that inputs respective RF signals to the sub-arrays 260-SA through 260-SD from an RF input port, such as a connector 140 (FIG. 1) of the antenna 100. Moreover, the switches 360 (FIG. 3B) of the sub-arrays 260-SB through 260-SD may be actuated by a high-voltage driver 350 that is coupled to the sub-arrays 260-SB through 260-SD. As an example, the driver 350 may be commonly coupled to each of the sub-arrays 260-SB through 260-SD, such as by a conductive line 380. Alternatively, the sub-arrays 260-SB through 260-SD may be coupled to respective drivers 350. The sub-array 260-SA, from which switches 360 are omitted, may not be coupled to any driver 350.

In some embodiments, the sub-arrays 260-SA through 260-SD (or the sub-arrays 260-SB through 260-SD) may be coupled to a decoder 340 that is configured to translate (a) information relating to an amount of tilt (e.g., electrical down-tilt) of the antenna 100, which has radiating elements 250 (FIG. 2A) that are coupled to the phase shifter 260-MT, into (b) a state of the phase shifter 260-MT. For example, the decoder 340 may be commonly coupled to each of the sub-arrays 260-SA through 260-SD, such as by a conductive line 380. Alternatively, the sub-arrays 260-SA through 260-SD may be coupled to respective decoders 340.

A storage device 370 may be configured to hold a state of the phase shifter 260-MT. For example, the storage device 370 may be coupled to the sub-arrays 260-SA through 260-SD (or the sub-arrays 260-SB through 260-SD), such as by a conductive line 380. As an example, the storage device 370 may comprise a capacitor that has a sufficiently-high capacitance to hold a high voltage of the phase shifter 260-MT. As a result, the capacitor can maintain a state of the phase shifter 260-MT even if power is lost for an extended period of time (e.g., multiple hours). Otherwise, switches 360 may revert to their default states in response to power loss. In some embodiments, each switch 360 (or each pair of switches 360) may be coupled to a respective capacitor that is configured to maintain a state of the switch 360 (or pair of switches 360). Alternatively, the storage device 370 may be a non-volatile memory, such as a flash memory, that is coupled to the phase shifter 260-MT. The storage device 370, along with control logic (e.g., a processor), can reset one or more switches 360 to their last state(s) after a power loss.

The following Table 3 illustrates the amount of delay that is provided by each state of the phase shifter 260-MT. In Table 3, the sub-arrays 260-SB through 260-SD are indicated as “Sub B,” “Sub C,” and “Sub D,” respectively. The phase shifter 260-MT can be used to provide multiple delayed versions of an input signal to feed various radiating elements 250 (FIG. 2A) of an antenna array to steer the array main beam to different angles. Table 3 shows an example of delay values of various switch paths that would provide incremental delayed versions of the input signal to steer the main lobe of the array response to a desired angle. In many antenna applications, this type of multi-tap control can be used as (i) an azimuth beam steering feature, (ii) an elevation beam tilt feature, or (iii) both (i) and (ii).

TABLE 3

| State | Sub B | Sub C | Sub D |
|---|---|---|---|
| 00 | Ref | Ref | Ref |
| 01 | T | 2T | 3T |
| 02 | 2T | 4T | 6T |
| 03 | 3T | 6T | 9T |
| 10 | 4T | 8T | 12T |
| 11 | 5T | 10T | 15T |
| 12 | 6T | 12T | 18T |
| 13 | 7T | 14T | 21T |
| 20 | 8T | 16T | 24T |
| 21 | 9T | 18T | 27T |
| 22 | 10T | 20T | 30T |
| 23 | 11T | 22T | 33T |
| 30 | 12T | 24T | 36T |
| 31 | 13T | 26T | 39T |
| 32 | 14T | 28T | 42T |
| 33 | 15T | 30T | 45T |

For antenna beam steering or tilt control applications, having a very low insertion loss may help the phase shifter 260-MT to avoid significant deterioration of a transmitted or received signal. Also, in many antenna applications for a frequency division duplex (“FDD”) system, the PIM performance of a phase shifter affects whether the phase shifter can avoid desensitizing a receiver by generating intermodulation product from a transmitter within a receive band. Accordingly, a switching approach that provides low loss and high linearity performance may be advantageous. Moreover, as a PIM requirement for an FDD digital phase shifter may be more strict than a PIM requirement for a TDD digital phase shifter, TDD operations may be more readily attainable for a digital phase shifter.

For simplicity of illustration, a single conductive line 380 is shown in FIG. 3C. In some embodiments, however, multiple conductive lines 380 may connect the sub-arrays 260-SA through 260-SD (or the sub-arrays 260-SB through 260-SD) to the decoder(s) 340, the driver(s) 350, and the storage device(s) 370. Moreover, a decoder 340, a driver 350, and a storage device 370 may be coupled to a four-state digital phase shifter 260-4S (FIG. 3A) or a sixteen-state digital phase shifter 260-16S (FIG. 3B), and are not limited to being connected to a multi-tap digital phase shifter 260-MT.

The multi-tap digital phase shifter 260-MT can be constructed using multiple sub-arrays having two-stage phase shifters, such as the phase shifter 260-16S. This multi-tap phase shifter 260-MT provides multiple delayed versions of an input signal at various outputs. Each branch of the multi-tap phase shifter 260-MT is configured to provide different ranges of total delay (e.g., different ranges of phase shift) along with different step sizes (e.g., (i) a step from a delay of REF to a delay of REF+T versus (ii) a step from a delay of REF to a delay of REF+2T).

Though the switches 360 are shown as four-throw switches, they may, in some embodiments, each have six, eight, or sixteen throws, for example. Moreover, the switches 360 may be respective RF MEMS switches. For example, the switches 360 may be direct-contact RF MEMS switches or capacitive RF MEMS switches. In some embodiments, the switches 360 may be high-power RF MEMS switches. An example of a high-power RF MEMS switch is an RF MEMS switch that can provide greater than 25 Watts of continuous wave (“CW”), or 150 Watts of pulsed wave, power handling at 6 gigahertz (“GHz”). Moreover, a high-power RF MEMS switch can, in some embodiments, also provide a low insertion loss of 0.35 decibels (“dB”) at 6 GHz, and may have a maximum voltage of 150 Volts at an RF input.

As used herein, the term “high-power RF MEMS switch” refers to an RF MEMS switch that has (a) a typical voltage of 60-150 Volts at an RF input and/or (b) greater than 10 Watts of CW (or 60 Watts of pulsed wave) power handling. Likewise, the term “high-voltage driver” refers to a driver that is configured to actuate a high-power RF MEMS switch by supplying at least 60-150 Volts at an RF input of the high-power RF MEMS switch.

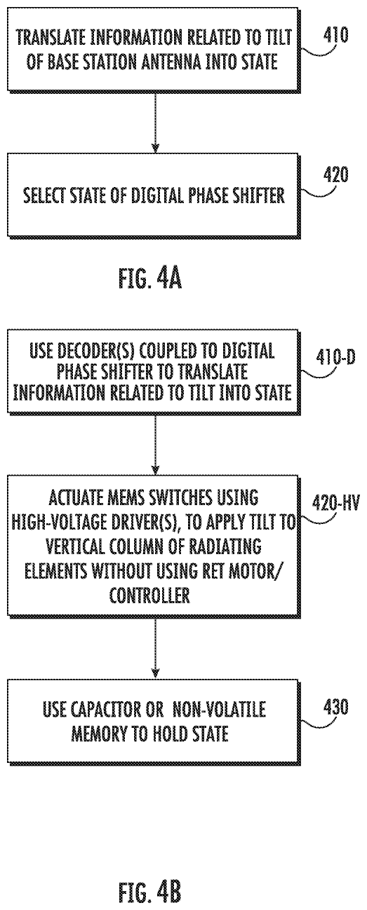

FIGS. 4A and 4B are flowcharts illustrating operations of a base station antenna 100 (FIG. 1) that includes a digital phase shifter 260 (FIGS. 3A-3C). As shown in FIG. 4A, the phase shifter 260 may select (Block 420), via first and second multi-throw RF switches 360-1 and 360-2 (FIG. 3A) that are coupled to each other by at least four delay lines 310 (FIG. 3A) having different respective lengths, a state of the phase shifter 260. Moreover, the phase shifter 260 may translate (Block 410) (a) information relating to an amount of tilt (e.g., electrical down-tilt) for a vertical column of radiating elements 250 (FIG. 2A) in the antenna 100 into (b) the state of the phase shifter 260. The information relating to the amount of tilt may be, for example, a value of electrical tilt (e.g., in degrees) and/or a value of time, and may be received at the phase shifter 260 from a controller of the antenna 100. Each vertical column of radiating elements 250 in the antenna 100 may be coupled to at least one phase shifter 260.

In some embodiments, the phase shifter 260 may include third and fourth multi-throw RF switches 360-3 and 360-4 (FIG. 3B) that are coupled to each other by at least four delay lines 310 (FIG. 3B) having different respective lengths. Accordingly, the phase shifter 260 may include first and second pairs of switches 360. Moreover, in some embodiments, the phase shifter 260 may include sub-arrays 260-SA through 260-SD (FIG. 3C), most of which have multiple pairs of switches 360.

As shown in FIG. 4B, the switches 360 may be respective RF MEMS switches, and selection (Block 420) of the state of the phase shifter 260 may include actuating (Block 420-HV) the RF MEMS switches via at least one high-voltage driver 350 (FIG. 3C). For example, the RF MEMS switches may be high-power RF MEMS switches. Moreover, translation (Block 410) into the state may be performed (Block 410-D) via at least one decoder 340 (FIG. 3C) that is coupled to the phase shifter 260.

In some embodiments, the phase shifter 260, which is coupled to a vertical column of radiating elements 250, may apply electrical tilt to the vertical column without using any RET actuator (e.g., RET motor/controller). Instead, the phase shifter 260 may apply the electrical tilt by actuating (Block 420-HV) the RF MEMS switches. The electrical tilt may, in some embodiments, be adjusted a few times per day. Because each phase shifter 260 is a digital phase shifter rather than a phase shifter having movement that is controlled by a RET actuator, RET actuators and associated mechanical linkages may be omitted from the antenna 100. Moreover, the phase shifter 260 may, in some embodiments, operate as a TDD digital phase shifter (i.e., operate in a TDD mode of the antenna 100) while applying the electrical tilt.

A storage device 370, such as a non-volatile memory or one or more capacitors, may be used (Block 430) to hold a state of the phase shifter 260. For example, the storage device 370 may hold the state after actuating (Block 420-HV) the RF MEMS switches to apply the electrical tilt. Even if the storage device 370 loses power for multiple hours, it may maintain the state. As an example, current into a switch 360 may be on the order of microamperes, and microfarads of capacitance may hold the state for multiple hours.

A digital phase shifter 260 (FIGS. 3A-3C) comprising multi-throw RF switches 360 (FIG. 3A) according to embodiments of the present inventive concepts may provide a number of advantages. These advantages include reduced size, weight, and cost, due to RET actuators not being necessary. For example, each stage, including a pair of switches 360 of the phase shifter 260, may be in a relatively small area of about 3 centimeters (“cm”) by 3 cm. Moreover, by using high-power RF MEMS switches for the switches 360, the phase shifter 260 may have a lower insertion loss than a conventional phase shifter. The high-power RF MEMS switches may also experience sufficiently-low PIM distortion to operate in a TDD mode of a base station antenna 100 (FIG. 1) that includes the high-power RF MEMS switches. Further, the phase shifter 260 may exponentially increase the number of phase or time delay increments by connecting multiple phase-shifter stages, such as by coupling the first and second groups of phase shifter stage switches 360-1S and 360-2S (FIG. 3B).

The present inventive concepts have been described above with reference to the accompanying drawings. The present inventive concepts are not limited to the illustrated embodiments. Rather, these embodiments are intended to fully and completely disclose the present inventive concepts to those skilled in this art. In the drawings, like numbers refer to like elements throughout. Thicknesses and dimensions of some components may be exaggerated for clarity.

Spatially relative terms, such as “under,” “below,” “lower,” “over,” “upper,” “top,” “bottom,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “under” or “beneath” other elements or features would then be oriented “over” the other elements or features. Thus, the example term “under” can encompass both an orientation of over and under. The device may be otherwise oriented (rotated 90 degrees or at other orientations) and the spatially relative descriptors used herein interpreted accordingly.

Herein, the terms “attached,” “connected,” “interconnected,” “contacting,” “mounted,” and the like can mean either direct or indirect attachment or contact between elements, unless stated otherwise.

Well-known functions or constructions may not be described in detail for brevity and/or clarity. As used herein the expression “and/or” includes any and all combinations of one or more of the associated listed items.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including” when used in this specification, specify the presence of stated features, operations, elements, and/or components, but do not preclude the presence or addition of one or more other features, operations, elements, components, and/or groups thereof.

That which is claimed is:

1. A digital phase shifter comprising:
a first phase shifter stage comprising first and second multi-throw radio frequency (RF) switches that are coupled to each other by a first plurality of delay lines having different respective lengths; and
a second phase shifter stage comprising third and fourth multi-throw RF switches that are coupled to each other by a second plurality of delay lines having different respective lengths,
wherein the second multi-throw RF switch of the first phase shifter stage is coupled to the third multi-throw RF switch of the second phase shifter stage.

2. The digital phase shifter of claim 1, further comprising a third phase shifter stage comprising fifth and sixth multi-throw RF switches that are coupled to each other by a third plurality of delay lines having different respective lengths,
wherein the fourth multi-throw RF switch of the second phase shifter stage is coupled to the fifth multi-throw RF switch of the third phase shifter stage.

3. The digital phase shifter of claim 1,
wherein the first and second phase shifter stages are in a first sub-array of a phase shift array, and
wherein the phase shift array further comprises:
a second sub-array comprising a second plurality of phase shifter stages;
a third sub-array comprising a third plurality of phase shifter stages; and
a fourth sub-array comprising a delay line that is not coupled to any multi-throw RF switch.

4. The digital phase shifter of claim 3, further comprising a power divider that is coupled to the first through fourth sub-arrays.

5. The digital phase shifter of claim 3, further comprising a high-voltage driver that is coupled to the first through third sub-arrays.

6. The digital phase shifter of claim 3,
wherein the digital phase shifter is coupled to radiating elements of a base station antenna, and
wherein the digital phase shifter further comprises a decoder that is coupled to the first through third sub-arrays and is configured to translate information relating to an amount of tilt of the base station antenna into a state of the digital phase shifter.

7. The digital phase shifter of claim 3, further comprising first through third decoders that are coupled to the first through third sub-arrays, respectively.

8. The digital phase shifter of claim 3, further comprising a storage device that is coupled to, and configured to hold a state of, the digital phase shifter.

9. The digital phase shifter of claim 8, wherein the storage device comprises a capacitor.

10. The digital phase shifter of claim 8, wherein the storage device comprises a non-volatile memory.

11. The digital phase shifter of claim 1, wherein the first through fourth multi-throw RF switches comprise respective RF microelectromechanical systems (MEMS) switches.

12. The digital phase shifter of claim 1, wherein the digital phase shifter is a time division duplex (TDD) digital phase shifter.

13. A digital phase shifter comprising first and second multi-throw radio frequency (RF) switches that are coupled to each other by at least four delay lines having different respective lengths.

14. The digital phase shifter of claim 13, further comprising third and fourth multi-throw RF switches that are coupled to each other by at least four delay lines having different respective lengths,
wherein the second and third multi-throw RF switches are coupled to each other.

15. A method of operating a base station antenna comprising a digital phase shifter, the method comprising:
translating information relating to an amount of tilt of the base station antenna into a state of the digital phase shifter; and
selecting, via first and second multi-throw radio frequency (RF) switches that are coupled to each other by at least four delay lines having different respective lengths, the state of the digital phase shifter.

16. The method of claim 15,
wherein the first and second multi-throw RF switches comprise first and second RF microelectromechanical systems (MEMS) switches, respectively, and
wherein the selecting comprises actuating the first and second RF MEMS switches via at least one high-voltage driver.

17. The method of claim 16, wherein the actuating comprises applying the amount of tilt to a vertical column of radiating elements coupled to the digital phase shifter, without using any RET motor.

18. The method of claim 15, wherein the translating is performed by at least one decoder coupled to the digital phase shifter.

19. The method of claim 15, further comprising using a capacitor or a non-volatile memory to hold the state of the digital phase shifter.

20. The method of claim 15, wherein the digital phase shifter operates in a time division duplex (TDD) mode of the base station antenna.
